(19) United States
(12) Patent Application Publication
(10) Pub. No.: US 2019/0310691 A1
(43) Pub. Date: Oct. 10, 2019

(54) CRYPTO CURRENCY MINING SYSTEM CAPABLE OF PRODUCING HOT WATER

(71) Applicant: Michael AHN, RIVER EDGE, NJ (US)

(72) Inventors: Michael AHN, RIVER EDGE, NJ (US); Ho Seong KO, Seoul (KR); Sung Soo Park, Daejeon (KR)

(21) Appl. No.: 16/377,934

(22) Filed: Apr. 8, 2019

(30) Foreign Application Priority Data
Apr. 6, 2018 (KR) 10-2018-0040211
Aug. 28, 2018 (KR) 10-2018-0101034

(51) Int. Cl. G06F 1/20; H05K 7/20; F24D 17/00; F24D 17/02

(52) U.S. Cl. CPC G06F 1/20; H05K 7/20309; F24D 17/02; H05K 7/20327; F24D 17/0089; H05K 7/203

(57) ABSTRACT

Provided is a crypto currency mining system capable of producing hot water, which includes a cooling system for cooling heat generated when a crypto current is mined and includes a hot water producing device for generating hot water by using the heat of cooling water, which passed through the cooling system, to reduce management and maintenance costs by recycling energy consumed when the crypto currency is mined, and improve productivity. The crypto currency mining system capable of producing hot water includes a calculation device for mining a crypto currency; a power supply device configured to supply electric power for an operation of the calculation device; a cooling system configured to cool heat generated by the calculation device or the power supply device through exchange of heat; and a hot water producing device configured to produce hot water by using the heat discharged from the cooling system.

### BACKGROUND OF THE INVENTION

### 1. Field of the Invention

The present invention relates to a crypto currency mining system capable of producing hot water, which includes a cooling system for cooling heat generated when a crypto currency is mined and can produce hot water through the cooling system to save energy.

### 2. Description of the Prior Art

In general, a crypto currency is a digital currency which is issued for a compensation when a specific password and an algorithm are encoded.

A bit coin, which is a representative crypto currency, does not have any central device, which issues and manages a currency, and bit coins are traded through a peer-to-peer (P2P) based distributed information database.

The bit coins are stored in the form of a purse file, and a unique address is given to the purse and the bit coins are traded based on the given unique address and a public key password scheme.

According to the crypto currency, such as a bit coin, a predetermined amount of bit coins are automatically and periodically produced according to a specific algorithm, and the ownership of the produced bit coins is handed over if a complex mathematical and encoded problem, which is produced through a specific algorithm, is solved.

The complex mathematical and encoded problem produced through a specific algorithm of a bit coin is solved by a GPU of an excellent calculation capacity mounted on a graphics card or a hash board rather than a CPU mounted on a main board of a computer, and the mining operation is performed, depending on the graphics card or a plurality of hash boards, on which a plurality of dedicated ASICs, which performs only calculations necessary for mining, are mounted.

Accordingly, the crypto currency mining system is used by connecting a plurality of graphics cards or a plurality of hash boards to one main board.

However, in a conventional crypto currency mining system, because a plurality of graphics cards or a plurality of hash boards, on which a plurality of ASICs dedicated for calculations are mounted, much heat is generated and a cooling system for cooling heat is provided.

The conventional cooling system is of an air cooling type, and a plurality of cooling fans are installed around the graphic cards to cool heat through convection. However, the air cooling type increases the volume of the device due to the plurality of cooling fans, consumes much electric power, and generates noise.

In addition, the cooling efficiency of the cooling fans deteriorates due to contact with a duct and the like when used for a long time, and maintenance and repair costs are generated, for example, because dust is stuck to the cooling fans or the cooling fans break down.

Further, because the conventional crypt currency mining system consumes much electric energy for mining and consumes energy for cooling heat, big costs are consumed for maintenance and management of the system, which deteriorates productivity.

### PRIOR TECHNICAL DOCUMENTS

### Patent Documents

(Patent Document 1) Korean Patent Application Publication No. 10-2014-0020060

### SUMMARY OF THE INVENTION

The present invention has been made in an effort to solve the above-mentioned problems, and provides a crypto currency mining system capable of producing hot water, which includes a cooling system for cooling heat generated when a crypto current is mined and includes a hot water producing device for generating hot water by using the heat of cooling water, which passed through the cooling system, to reduce management and maintenance costs by recycling energy consumed when the crypto currency is mined, and improve productivity.

In accordance with an aspect of the present invention, there is provided a crypto currency mining system capable of producing hot water, the crypto currency mining system including: a calculation device for mining a crypto currency; a power supply device configured to supply electric power for an operation of the calculation device; a cooling system configured to cool heat generated by the calculation device or the power supply device through exchange of heat; and a hot water producing device configured to produce hot water by using the heat discharged from the cooling system.

The cooling system may include: a housing in which a liquid refrigerant is accommodated in the interior thereof, and in which the calculation device or the power supply device is installed to be submerged in the liquid refrigerant; a cooling pipe installed in the interior of the housing and disposed above the liquid refrigerant to cool the liquid refrigerant, which is vaporized; a cooling water circulating pump configured to supply cooling water to the cooling pipe; and a heat exchange device configured to cool the cooling water which exits from the cooling pipe after being heated, and the hot water producing device may be disposed between the cooling water circulating pump and the heat exchange device.

A metallic sheet formed of a porous metallic material may be provided above or below the cooling pipe, and the metallic sheet may cool the vaporized liquid refrigerant to convert a state of the vaporized liquid refrigerant to a liquefied state.

The metallic sheet may be formed of a copper foam manufactured by expanding copper.

The sizes of pores of the metallic sheet may be 35 to 45 pore per inch (ppi) and the porosity of the metallic sheet may be 90 to 94%.

A contact part disposed above the liquid refrigerant and bent in zigzags at a predetermined interval may be formed in the cooling pipe, and the metallic sheet may be disposed above or below the contact part and may be coupled to the contact part through brazing.

The hot water producing device may include: a hot water storage in which water is stored; a heat exchange pipe disposed in the interior of the hot water storage and configured to exchange heat with the cooling water supplied from the cooling pipe to be heated, and heat the water stored in the hot water storage; a discharge pipe through which the water stored in the hot water storage is discharged; a supply pump configured to supply the water stored in the hot water storage to the discharge pipe; and an injection pipe configured to inject water into the hot water storage when hot water is discharged through the discharge pipe.

The cooling system may include: a housing in which a liquid refrigerant is accommodated in the interior thereof, and in which the calculation device or the power supply device is installed to be submerged in the liquid refrigerant; a supply pipe configured to supply the cooled liquid refrigerant to the housing; a recovery pipe configured to recover the liquid refrigerant heated in the housing; a heat exchange device mounted between the supply pipe and the recovery pipe and configured to cool the heated liquid refrigerant; and a cooling water circulating pump configured to circulate the liquid refrigerant along the supply pipe, the recovery pipe, and the housing, and the hot water producing device may be disposed between the cooling water circulating pump and the heat exchange device.

The hot water producing device may include: a hot water storage in which water is stored; a heat exchange pipe disposed in the interior of the hot water storage and configured to exchange heat with the liquid refrigerant supplied from the recovery pipe to be heated, and heat the water stored in the hot water storage; a discharge pipe through which the water stored in the hot water storage is discharged; a supply pump configured to supply the water stored in the hot water storage to the discharge pipe; and an injection pipe configured to inject water from the outside into the hot water storage if the water level of the hot water storage is a predetermined height or less.

The liquid refrigerant may be a material which is vaporized at 60° C. or more, and is a nonconductive material.

### BRIEF DESCRIPTION OF THE DRAWINGS

The above and other objects, features, and advantages of the present invention will be more apparent from the following detailed description taken in conjunction with the accompanying drawings, in which:

FIG. 1 is a perspective view illustrating a part of a crypto currency mining system capable of producing hot water according to a first embodiment of the present invention;

FIG. 2 is a sectional view illustrating an internal structure of a housing of the crypto currency mining system capable of producing hot water according to the first embodiment of the present invention;

FIG. 3 is a perspective view illustrating an entire configuration of the crypto currency mining system capable of producing hot water according to the first embodiment of the present invention;

FIG. 4 is a view briefly illustrating a production amount of the crypto currency mining system capable of producing hot water according to the first embodiment of the present invention;

FIG. 5 is a diagram view illustrating an entire configuration of a crypto currency mining system capable of producing hot water according to a second embodiment of the present invention; and

FIG. 6 is a structural view of a hot water producing device according to the second embodiment of the present invention.

### DETAILED DESCRIPTION OF THE EXEMPLARY EMBODIMENTS

### First Embodiment

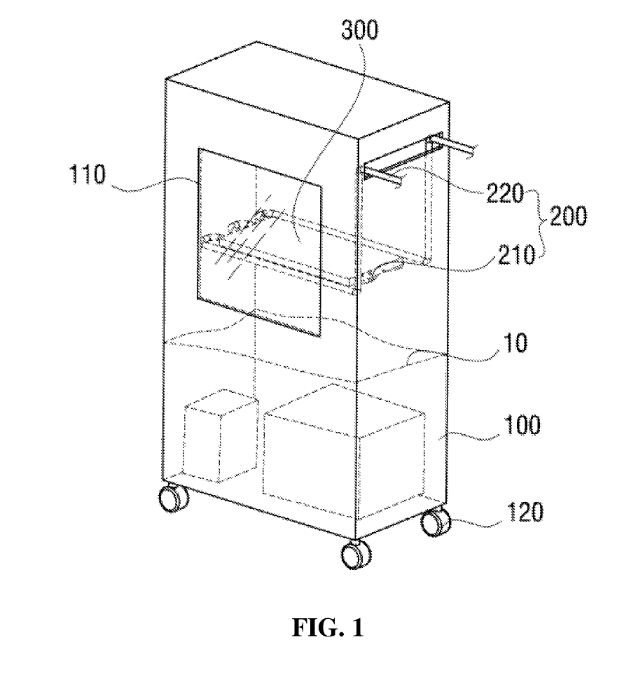

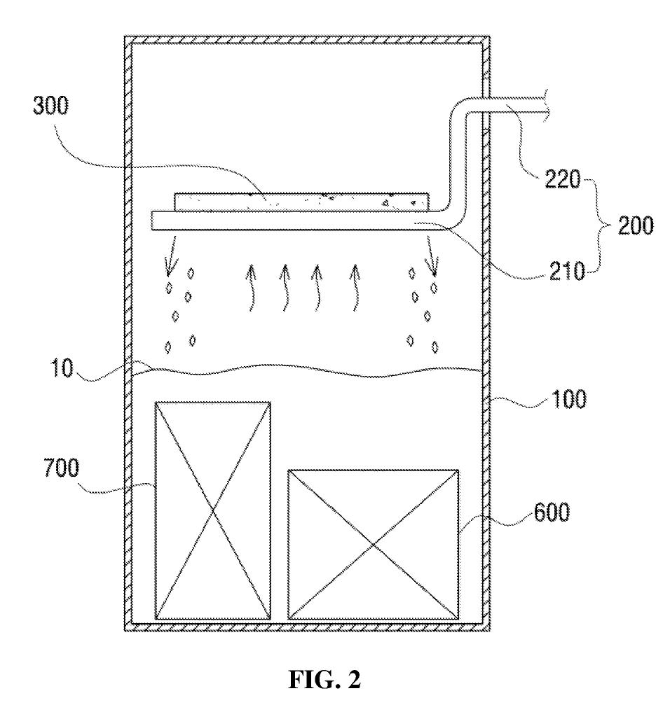

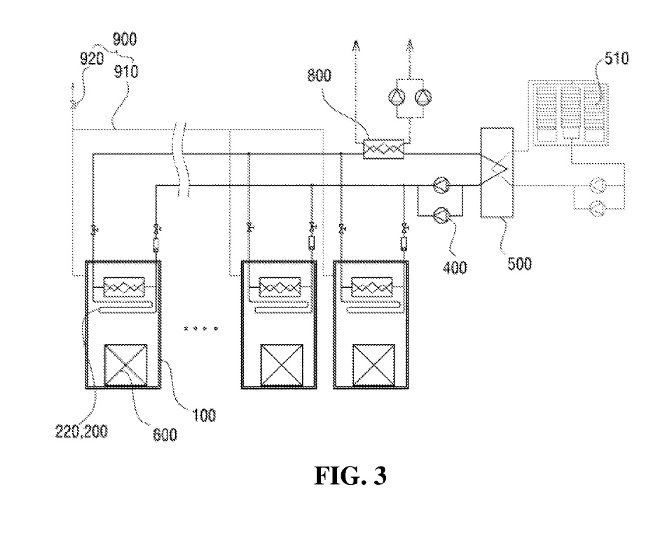

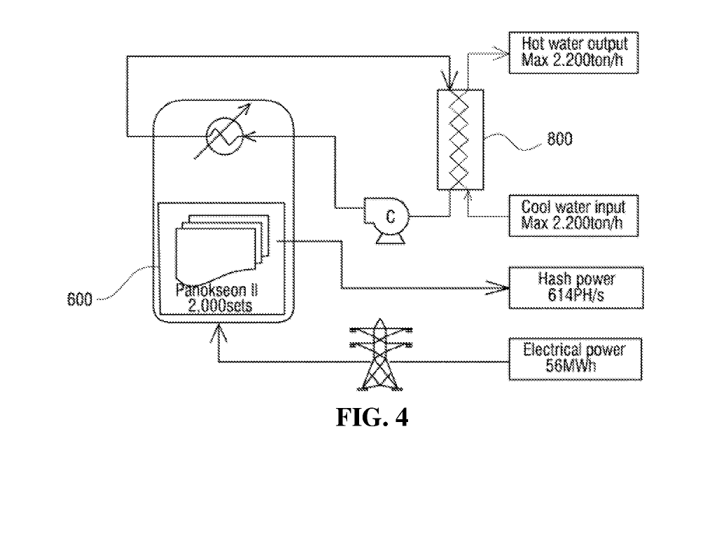

FIG. 1 is a perspective view illustrating a part of a crypto currency mining system capable of producing hot water according to a first embodiment of the present invention. FIG. 2 is a sectional view illustrating an internal structure of a housing of the crypto currency mining system capable of producing hot water according to the first embodiment of the present invention. FIG. 3 is a perspective view illustrating an entire configuration of the crypto currency mining system capable of producing hot water according to the first embodiment of the present invention. FIG. 4 is a view briefly illustrating a production amount of the crypto currency mining system capable of producing hot water according to the first embodiment of the present invention.

As illustrated in FIGS. 1 to 4, the crypto currency mining system capable of producing hot water according to the first embodiment of the present invention includes a calculation device 600, a power supply device 700, a cooling system, and a hot water producing device 800.

The calculation device 600 is a device used for mining of a crypto currency, and includes a mainboard, and a plurality of graphics cards mounted on the main board or a plurality of hash boards, on which a plurality of calculation-dedicated ASICs are mounted.

Then, because the graphics cards or the hash boards generate much heat, the calculation device 600 is cooled by the cooling system, which will be described below.

The power supply device 700 supplies electric power, which is necessary for an operation of the calculation device 600, and is a power supply generally used in a computer.

The power supply device 700 receives external electric power of 220 V, and converts the AC power to a DC power having a lower voltage and supplies the DC power to the calculation device 600.

Because the power supply device 700 generates much heat, it is cooled by the cooling system like the calculation device 600.

Meanwhile, the cooling system includes a housing 100, a cooling pipe 200, a metallic sheet 300, a cooling water circulating pump 400, and a heat exchange device 500.

The housing 100 has a rectangular parallelepiped shape, and has a space for accommodating a liquid refrigerant 10 in the interior thereof.

Here, the liquid refrigerant 10 is a material which is vaporized at 60° C. or more, and is a nonconductive liquid which is not damaged even through an electronic component is submerged in the liquid refrigerant 10.

In the first embodiment of the present invention, NOVEC 7100 of 3M Inc. is used as the liquid refrigerant 10

The calculation device 600 and the power supply device 700 are installed in the interior of the housing 100 to be submerged in the liquid refrigerant 10.

Further, an identification window 110 for identifying an internal situation is formed on a front surface of the housing 100.

The identification window 110 is formed of a transparent plate and is adapted for identifying an internal situation by naked eyes.

Further, wheels 120 for movement are provided at lower ends of the housing 100 to facilitate movement of the system.

The wheels 120 are provided around apexes of the bottom surface of the housing 100, respectively, and are easily pushed for movement if the housing 100 is pushed by hands.

Further, as illustrated in FIG. 3, the housing 100 may include a plurality of sets for cooling the plurality of calculation devices.

Meanwhile, the cooling pipe 200 cools heat while cooling water flows in the interior thereof, and includes a contact part 210 and a circulation part 220.

The contact part 210 of the cooling pipe 200 is disposed above the liquid refrigerant 10, and is bent in zigzags at a predetermined interval.

The contact part 210 contacts the liquid refrigerant 10, which is vaporized, to cool the liquid refrigerant 10 and return the state of the liquid refrigerant 10 to the liquid state.

The contact part 210 includes the metallic sheet 300, which will be described below.

The circulation part 220 extends from the contact part 210, and is connected to the heat exchange device 500, which will be described below.

The metal sheet 300 is formed of a porous metallic material, in detail, a copper foam obtained by expanding copper and has a flat rectangular shape.

Further, it is preferable that the sizes of the pores of the metallic sheet 300 are 35 to 45 pore per inch (ppi) and the porosity of the pores is 90 to 94%.

If the sizes of the pores of the metallic sheet 300 are 45 ppi or more, the areas of the metallic sheet 300, which contact the liquid refrigerant, decreases and cooling efficiency decreases, and if the sizes of the pores of the metallic sheet 300 are 35 ppi or less, water drops are generated in the pores and obstructs circulation of gas, deteriorating cooling efficiency.

The metallic sheet 300 is disposed above the contact part 210, and is coupled to the contact part 210 through brazing.

Here, the brazing uses hard solder, and is a technology of welding two base materials, which are to be welded, by adding a filter metal and heat while the base materials are not damaged, at the melting points of the base materials of 450° C. or more.

According to occasions, the metallic sheet 300 may be disposed below the contact part 210.

The metallic sheet 30 functions to maximize a contact area with the vaporized liquid refrigerant 10 and promptly cool the liquid refrigerant 10 through exchange of heat with the cooling pipe 200.

Meanwhile, the cooling water circulating pump 400 supplies the cooling water to the cooling pipe 200, and the cooling water circulates along the cooling pipe 200.

The heat exchange device 500 cools the cooling water, which exits from the cooling pipe 200 after being heated, and in detail, includes a cooling tower 510 which directly brings the cooling water into contact with the exterior air and cooling the cooling water.

The cooling device including the metal sheet according to the first embodiment of the present invention submerges an object to be cooled in the liquid refrigerant 10 in the interior of the housing 100, and the liquid refrigerant 10 contacts the cooling pipe 200 and the metallic sheet 300 while being vaporized by the heat, and then, the liquid refrigerant 10 is cooled through exchange of heat and is converted into a liquid state again and drops to the lower side.

In particular, the metallic sheet 300 increases the contact area with the vaporized liquid refrigerant 10 and thus increases total cooling efficiency by a large degree.

Further, the hot water producing device 800, which produces hot water by using heat discharged from the cooling pipe 200, may be connected.

The hot water producing device 800 uses the heat of the cooling pipe 200 discharged after cooling the liquid refrigerant in the housing, and produces hot water by heating water through exchange of heat, and may be used for a heating device or a spa facility.

Further, an adjustment unit 900 for discharging internal gas to the outside when the interior of the housing 100 is overheated and the pressure in the housing 100 is raised.

The adjustment unit 900 includes a discharge pipe 910 connected to the housing 100 and an opening/closing valve 920 which opens and closes the discharge pipe 910.

The adjustment unit 900 can prevent an accident, such as an explosion, by discharging internal gas to the outside when the pressure of the interior of the housing 100 is raised, and accordingly, safety can be improved.

The crypto currency mining system having the cooling device including the metal sheet according to the first embodiment can promptly cool the calculation device 600 and the power supply device 700, which generate much heat, by disposing the calculation device 600 and the power supply device 700 such that the calculation device 600 and the power supply device 700 are submerged in the housing 100, in which the liquid refrigerant 10 is accommodated.

In particular, cooling efficiency can be further increased by providing the porous metallic sheet 300 in the cooling pipe 200 to cool the liquid refrigerant 10, which is vaporized at a low temperature.

Further, as illustrated in FIG. 4, when 2000 sets of calculation devices 600 are operated, electrical energy of 56 MWh is consumed and crypto currencies are produced at 614 PH/s, and additionally, hot water of 2000 ton/h can be produced by the hot water producing device, which increases economic gains and productivity.

### Second Embodiment

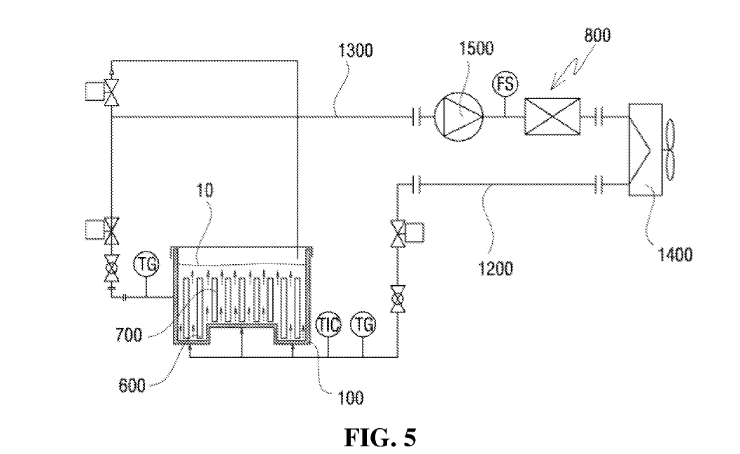

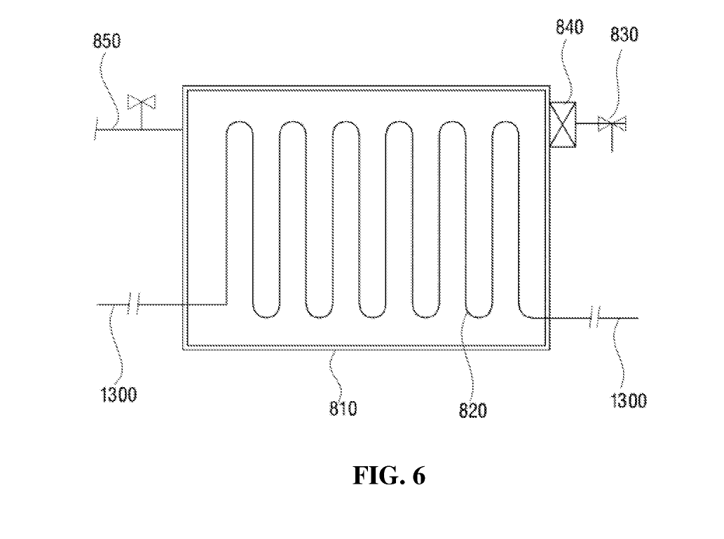

FIG. 5 is a diagram illustrating an entire configuration of a crypto currency mining system capable of producing hot water according to a second embodiment of the present invention. FIG. 6 is a structural view of a hot water producing device according to the second embodiment of the present invention.

As illustrated in FIGS. 5 and 6, the crypto currency mining system capable of producing hot water according to the second embodiment of the present invention includes a calculation device 600, a power supply device 700, a cooling system, and a hot water producing device 800.

The calculation device 600 is a device used for mining of a crypto currency, and includes a mainboard, and a plurality of graphics cards mounted on the main board or a plurality of hash boards, on which a plurality of calculation-dedicated ASICs are mounted.

Then, because the graphics cards or the hash boards generate much heat, the calculation device 600 is cooled by the cooling system, which will be described below.

The power supply device 700 supplies electric power, which is necessary for an operation of the calculation device 600, and is a power supply generally used in a computer.

The power supply device 700 receives external electric power of 220 V, and converts the AC power to a DC power having a lower voltage and supplies the DC power to the calculation device 600.

Because the power supply device 700 generates much heat, it is cooled by the cooling system like the calculation device 600.

Meanwhile, the cooling system includes a housing 100, a supply pipe 1200, a recovery pipe 1300, and a cooling water circulation pump 1500.

The housing 100 has a rectangular parallelepiped shape, and has a space for accommodating a liquid refrigerant 10 in the interior thereof.

Here, the liquid refrigerant 10 is a nonconductive liquid.

The calculation device 600 and the power supply device 700 are installed in the interior of the housing 100 to be submerged in the liquid refrigerant 10.

Further, although not illustrated in the drawings in detail, an identification window 110 for identifying an internal situation is formed on the front side of the housing 100 as in the first embodiment.

The identification window 110 is formed of a transparent plate and is adapted for identifying an internal situation by naked eyes.

Further, wheels 120 for movement are provided at lower ends of the housing 100 to facilitate movement of the system.

The wheels 120 are provided around apexes of the bottom surface of the housing 100, respectively, and are easily pushed for movement if the housing 100 is pushed by hands.

Further, as illustrated in FIG. 3, the housing 100 may include a plurality of sets for cooling the plurality of calculation devices.

The supply pipe 1200 is a pipe for supplying the liquid refrigerant 10, which has been cooled by the heat exchange device 1400, to the housing, and one end of the supply pipe 1200 is connected to a lower side of the housing 100 and an opposite side of the supply pipe 1200 is connected to the heat exchange device 1400.

The recovery pipe 1300 is a pipe for recovering the liquid refrigerant 10 heated in the housing 100 to the heat exchange device 1400, and one end of the recovery pipe 1300 is connected to an intermediate part of the housing 100 and an opposite end of the recover pipe 1300 is connected to the heat exchange device 1400 via the hot water producing device 800.

The heat exchange device 1400 is a device which is mounted between the supply pipe 1200 and the recovery pipe 1300 to cool the liquid refrigerant 10, and is of an air cooling type.

The cooling water circulating pump 1500 is mounted on the recovery pipe 1300, and circulates the liquid refrigerant along the supply pipe 1200, the recovery pipe 1300, and the housing 100.

Meanwhile, the hot water producing device 800 is a device which generates hot water by using the heat of the liquid refrigerant 10, which is recovered by the recovery pipe 1300, and is disposed between the cooling water circulating pump 1500 and the heat exchange device 1400.

In more detail, as illustrated in FIG. 6, the hot water producing device 800 includes a hot water storage 810, a heat exchange pipe 820, a discharge pipe 830, a supply pump 840, and an injection pipe 850.

The hot storage 810 is a vessel in which water to be used for hot water is stored.

The heat exchange pipe 820 is connected to the recovery 1300 and is connected to the recovery pipe 1300, and is disposed in the interior of the hot water storage 810 to heat the water stored in the hot storage 810.

The heat exchange pipe 820 has a zigzag shape to be stayed in the hot water storage 810 for a long time.

The discharge pipe 830 is a pipe, by which the hot water stored in the hot storage is used, and is connected to the heating pipe when the hot water is used for heating water and the faucet valve is installed in the discharge pipe 830 to be opened and closed if necessary when the heating pipe is used for drinking or washing.

Here, the supply pump 840 is mounted on the discharge pipe 830 to discharge the hot water discharged from the hot water storage at a predetermined pressure.

The supply pump 840 discharges the water stored in the hot water storage to be discharged to the discharge pipe 830 at a predetermined pressure when the discharge pipe 830 is opened.

The injection pipe 850 is a pipe through which water is injected from the outside to the hot water storage 810 if the water level of the hot water storage 810 is a predetermined height or less.

The crypto currency mining system capable of producing hot water according to the second embodiment of the present invention can increases cooling efficiency while having a simplified structure, by disposing the calculation device 600 and the power supply device 700 in the housing 100 such that the calculation device 600 and the power supply device 700 are completely submerged in the liquid refrigerant 10.

In particular, the liquid refrigerant 10 can be primarily cooled by installing the hot water producing device in the recovery pipe 1300 and exchanging heat of the liquid refrigerant 10 recovered to the recovery pipe 1300 with the water stored in the hot water storage, and energy can be saved by producing hot water, and productivity can be improved.

The crypto currency mining system capable of producing hot water according to the present invention has the following effects.

Because the cooling system for cooling heat generated when a crypto currency is mined is provided and the hot water producing device for producing hot water by using heat of cooling water, which has passes through the cooling system is provided, management and maintenance costs can be reduced and productivity can be improved by recycling energy consumed when the crypto currency is mined.

The calculation device 600 and the power supply device 700, which generate much heat, can be promptly cooled by disposing the calculation device 600 and the power supply device 700 such that the calculation device 600 and the power supply device 700 are submerged in the housing 100, in which the liquid refrigerant 10 is accommodated.

In particular, cooling efficiency can be further increased by providing the porous metallic sheet 300 in the cooling pipe 200 to cool the liquid refrigerant 10, which is vaporized at a low temperature.

The present invention is not limited thereto, and may be modified in various forms by those skilled in the art without departing from the spirit of the present invention, and the modifications can be construed to fall within the scope of the present invention.

What is claimed is:

1. A crypto currency mining system capable of producing hot water, the crypto currency mining system comprising:
a calculation device for mining a crypto currency;
a power supply device configured to supply electric power for an operation of the calculation device;
a cooling system configured to cool heat generated by the calculation device or the power supply device through exchange of heat; and
a hot water producing device configured to produce hot water by using the heat discharged from the cooling system.

2. The crypto currency mining system of claim 1, wherein the cooling system includes:
a housing in which a liquid refrigerant is accommodated in the interior thereof, and in which the calculation device or the power supply device is installed to be submerged in the liquid refrigerant;
a cooling pipe installed in the interior of the housing and disposed above the liquid refrigerant to cool the liquid refrigerant, which is vaporized;
a cooling water circulating pump configured to supply cooling water to the cooling pipe; and
a heat exchange device configured to cool the cooling water which exits from the cooling pipe after being heated, and
wherein the hot water producing device is disposed between the cooling water circulating pump and the heat exchange device.

3. The crypto currency mining system of claim 2, wherein a metallic sheet formed of a porous metallic material is provided above or below the cooling pipe, and
wherein the metallic sheet cools the vaporized liquid refrigerant to convert a state of the vaporized liquid refrigerant to a liquefied state.

4. The crypto currency mining system of claim 3, wherein the metallic sheet is formed of a copper foam manufactured by expanding copper.

5. The crypto currency mining system of claim 4, wherein the sizes of pores of the metallic sheet are 35 to 45 pore per inch (ppi) and the porosity of the metallic sheet is 90 to 94%.

6. The crypto currency mining system of claim 3, wherein a contact part disposed above the liquid refrigerant and bent in zigzags at a predetermined interval is formed in the cooling pipe, and
wherein the metallic sheet is disposed above or below the contact part and is coupled to the contact part through brazing.

7. The crypto currency mining system of claim 2, wherein the hot water producing device includes:
a hot water storage in which water is stored;
a heat exchange pipe disposed in the interior of the hot water storage and configured to exchange heat with the cooling water supplied from the cooling pipe to be heated, and heat the water stored in the hot water storage;
a discharge pipe through which the water stored in the hot water storage is discharged;
a supply pump configured to supply the water stored in the hot water storage to the discharge pipe; and
an injection pipe configured to inject water into the hot water storage when hot water is discharged through the discharge pipe.

8. The crypto currency mining system of claim 1, wherein the cooling system includes:
a housing in which a liquid refrigerant is accommodated in the interior thereof, and in which the calculation device or the power supply device is installed to be submerged in the liquid refrigerant;
a supply pipe configured to supply the cooled liquid refrigerant to the housing;
a recovery pipe configured to recover the liquid refrigerant heated in the housing;
a heat exchange device mounted between the supply pipe and the recovery pipe and configured to cool the heated liquid refrigerant; and
a cooling water circulating pump configured to circulate the liquid refrigerant along the supply pipe, the recovery pipe, and the housing, and
wherein the hot water producing device is disposed between the cooling water circulating pump and the heat exchange device.

9. The crypto currency mining system of claim 8, wherein the hot water producing device includes:
a hot water storage in which water is stored;
a heat exchange pipe disposed in the interior of the hot water storage and configured to exchange heat with the liquid refrigerant supplied from the recovery pipe to be heated, and heat the water stored in the hot water storage;
a discharge pipe through which the water stored in the hot water storage is discharged;
a supply pump configured to supply the water stored in the hot water storage to the discharge pipe; and
an injection pipe configured to inject water from the outside into the hot water storage if the water level of the hot water storage is a predetermined height or less.

10. The crypto currency mining system of claim 2, wherein the liquid refrigerant is a material which is vaporized at 60° C. or more, and is a nonconductive material.
